(19) United States
(12) Patent Application Publication
(10) Pub. No.: US 2009/0121339 A1
(43) Pub. Date: May 14, 2009

(54) SEMICONDUCTOR MODULE AND IMAGE PICKUP APPARATUS

(76) Inventors: Satoshi Noro, Anpachi-Gun (JP); Tomofumi Watanabe, Hashima-gun (JP)

Correspondence Address: MCDERMOTT WILL & EMERY LLP, 600 13TH STREET, N.W., WASHINGTON, DC, 20005-3096, US

(21) Appl. No.: 12/271,340

(22) Filed: Nov. 14, 2008

(30) Foreign Application Priority Data
Nov. 14, 2007 (JP) JP 2007-296150

(51) Int. Cl. H01L 23/498; H01L 31/00

(52) U.S. Cl. 257/693; 257/433; 348/208.6; 257/E23.006; 257/E31.001

(57) ABSTRACT

In a semiconductor module including multiple semiconductor devices, a signal that flows through a bonding wire connected to one semiconductor device is prevented from acting as noise which affects another semiconductor device, thereby improving the operation reliability of the semiconductor module. A second semiconductor device provided alongside a first semiconductor device includes a current output electrode via which large current is output. The current output electrode is electrically connected to a substrate electrode provided to a first wiring layer via a bonding wire such as a gold wire. The bonding wire is provided across the side E2 of the second semiconductor device. The bonding wire connected to the first semiconductor device is provided across a side of the first semiconductor device that corresponds to the side El of the second semiconductor device, i.e., the side F2, F3, or F4 of the first semiconductor device.

### CROSS-REFERENCE TO RELATED APPLICATIONS

This application is based upon and claims the benefit of priority from the prior Japanese Patent Application No.2007-296150, filed on Nov. 14, 2007, the entire contents of which are incorporated herein by reference.

### BACKGROUND OF THE INVENTION

1. Field of the Invention

The present invention relates to a semiconductor module and an image pickup apparatus mounting the semiconductor module.

2. Description of the Related Art

In recent years, improvement of the functions of electronic devices with a reduced size has involved an increased demand for providing a semiconductor module, which is to be employed in such an electronic device, with an even smaller size in a further integrated form. In order to meet such a demand, the MCM (multi-chip module), which mounts multiple semiconductor chips on a substrate, has been developed.

As an MCM structure which mounts semiconductor chips, a multi-stage stack structure is known in which multiple semiconductor chips are stacked. In an MCM having such a multi-stage stack structure, external electrodes are provided in the perimeter of each semiconductor chip. Furthermore, each external electrode is connected via a bonding wire to a corresponding electrode pad formed on the substrate.

Such an MCM is mounted on a CCD camera as a built-in component, for example. Each semiconductor chip has its own function. For example, a control circuit is formed as a built-in circuit on a semiconductor chip which provides a function as a logic device element. Also, a circuit which supplies current to a motor which drives a CCD is formed as a built-in circuit on a semiconductor chip that provides a function as a driver device element.

### DISCLOSURE OF THE INVENTION

### [Problems to be Solved by the Invention]

As such MCMs have come to be provided with higher circuit density, a semiconductor device which provides a function as a driver device and a semiconductor device which provides a function as a logic device are mounted further closer to each other in the form of a package. Accordingly, in some cases, a signal, which flows through a bonding wire connected to the semiconductor device which provides a function as a driver device, acts as noise which affects the semiconductor device which provides a function as a logic device. This reduces the operation reliability of the semiconductor device having a function as a logic device. Accordingly, this reduces the operation reliability of the semiconductor module.

Furthermore, there is a demand for providing an image pickup apparatus such as a digital camera with an even smaller size. The MCM has a problem in that the mounting of adjacent semiconductor devices further closer to one another markedly reduces the operation reliability of the aforementioned semiconductor devices, leading to malfunctioning of the image pickup apparatus.

### SUMMARY OF THE INVENTION

The present invention has been made in view of such a problem. Accordingly, it is a general purpose of the present invention to provide a technique for preventing a signal that flows through a bonding wire connected to one semiconductor device from acting as noise which affects the other semiconductor devices in a semiconductor module having multiple semiconductor devices, thereby improving the operation reliability of the semiconductor module. Also, it is another general purpose of the present invention to provide a technique for improving the operation reliability of an image pickup apparatus mounting a semiconductor module having multiple semiconductor devices in the form of a built-in semiconductor module.

### [Means for Solving the Problems]

An embodiment of the present invention relates to a semiconductor module. The semiconductor module comprises: a wiring substrate including substrate electrodes on one main surface thereof; a first semiconductor device which is mounted on the wiring substrate, and which includes a logic signal electrode via which a logic signal is input or output; a second semiconductor device which is mounted alongside the first semiconductor device, and which includes a current output electrode via which large current is output; a first bonding wire which electrically connects the logic signal electrode and the corresponding substrate electrode; and a second bonding wire which electrically connects the current output electrode and the corresponding substrate electrode. With such an embodiment, as viewed from the main surface side of the wiring substrate, the first bonding wire is provided across a side of the first semiconductor device that does not face a side of the second semiconductor device.

With such an embodiment, the logic signal electrode and the first bonding wire provided to the first semiconductor device are arranged so as to be distanced from the second semiconductor device. Thus, such an embodiment prevents noise from occurring in the first semiconductor device due to the effect of large current output from the second semiconductor device.

With such an embodiment, the current output electrode may be provided along a side of the second semiconductor device across which the second bonding wire is provided.

Also, with such an embodiment, the first semiconductor device may output a camera shake correction signal used to correct blurring due to camera shake applied to an image pickup apparatus. Also, the second semiconductor device may output large current to be supplied to a driving means which drives a lens of the image pickup apparatus according to the camera shake correction signal. With such an arrangement, the driving means may be a voice coil motor.

Also, with such an embodiment, the logic signal electrode may be provided along a side of the first semiconductor device that differs from a side facing a side of the second semiconductor device. Also, the distance between the side of the second semiconductor device across which the second bonding wire is provided and the side of the wiring substrate facing the aforementioned side may be smaller than the distance between the opposite side of the second semiconductor device opposite to the side across which the second bonding wire is provided and the side of the wiring substrate facing the opposite side. With such an arrangement, the first semiconductor device and the second semiconductor device may be arranged with an offset with respect to one another in the direction orthogonal to the side of the second semiconductor device across which the second bonding wire is provided.

Another embodiment of the present invention relates to an image pickup apparatus. The aforementioned image pickup apparatus includes a semiconductor module according to any one of the above-described embodiments.

### BRIEF DESCRIPTION OF THE DRAWINGS

Embodiments will now be described, by way of example only, with reference to the accompanying drawings which are meant to be exemplary, not limiting, and wherein like elements are numbered alike in several Figures, in which:

FIG. 1 is a block diagram which shows a circuit configuration of an image pickup apparatus including a semiconductor module according to an embodiment;

FIG. 2 is a plan view which shows a schematic configuration of the semiconductor module according to the embodiment;

FIG. 3 is a cross-sectional diagram which shows a schematic configuration of the semiconductor module according to the embodiment; and

FIG. 4 is a transparent perspective view which shows a digital camera including the semiconductor module according to the embodiment.

### DETAILED DESCRIPTION OF THE INVENTION

The invention will now be described by reference to the preferred embodiments. This does not intend to limit the scope of the present invention, but to exemplify the invention.

Description will be made regarding an embodiment according to the present invention with reference to the drawings. It should be noted that, in all the drawings, the same components are denoted by the same reference numerals, and detailed description thereof will be omitted as appropriate in the following description.

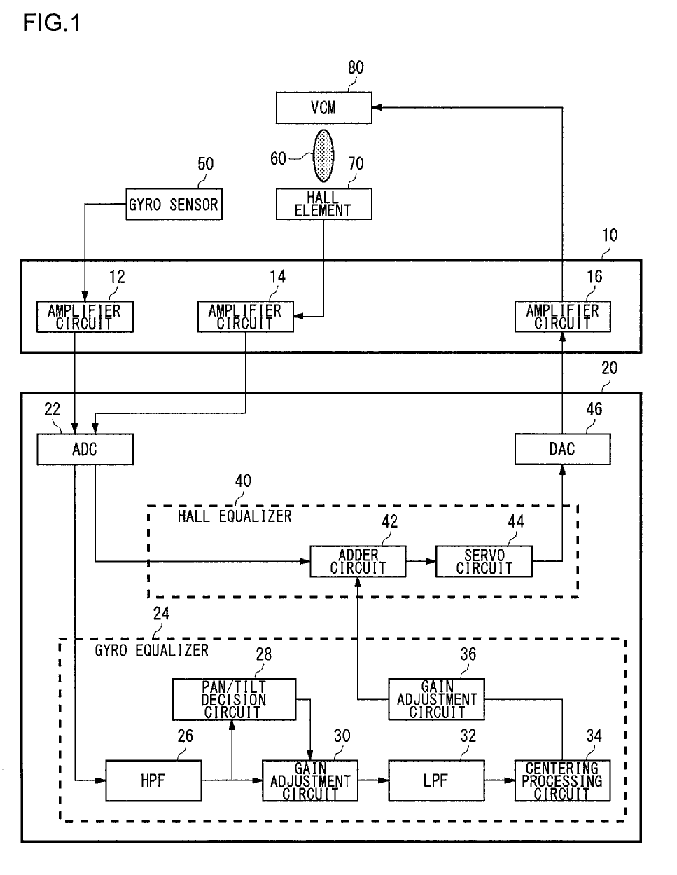

A semiconductor module according to the embodiment is suitably employed for an image pickup apparatus such as a digital camera etc., having a camera shake correction function (an anti-shake function). FIG. 1 is a block diagram which shows a circuit configuration of an image pickup apparatus having a semiconductor module according to the embodiment. A digital camera includes a signal amplifier unit 10 and a camera shake correction unit(an anti-shake unit) 20. The signal amplifier unit 10 amplifies an input signal with a predetermined gain, and outputs the signal thus amplified to the camera shake correction unit 20. The camera shake correction unit 20 outputs a signal, which is used to control the lens position so as to perform camera shake correction, to the signal amplifier unit 10 based upon an input angular velocity signal and an input lens position signal.

Specific description will be made regarding a circuit configuration of a digital camera.

A gyro sensor 50 detects the angular velocity along two axes, i.e., the X axis and the Y axis of a digital camera. The angular velocity signal acquired by the gyro sensor 50 in the form of an analog signal is amplified by an amplifier circuit 12, following which the angular velocity signal thus amplified is output to an ADC (analog/digital converter) 22. The ADC 22 converts the angular velocity signal thus amplified by the amplifier circuit 12 into an angular velocity signal in the form of a digital signal. The angular velocity signal output from the ADC 22 is output to a gyro equalizer 24.

In the gyro equalizer 24, first, the digital angular velocity signal output from the ADC 22 is input to an HPF (high-pass filter) 26. The HPF 26 removes frequency components that are lower than the frequency components due to camera shake from the angular velocity signal output from the gyro sensor 50. In general, the frequency components due to camera shake are within a range of 1 to 20 Hz. Accordingly, the frequency components which are equal to or lower than 0.7 Hz are removed from the angular velocity signal, for example.

A pan/tilt decision circuit 28 detects panning movement and tilting movement of the image pickup apparatus based upon the angular velocity signal output from the HPF 26. When the image pickup apparatus is moved according to the movement of the subject or the like, the gyro sensor 50 outputs an angular velocity signal according to the movement. However, change in the angular velocity signal due to the panning movement or tilting movement is not the result of camera shake. Accordingly, in some cases, there is no need to correct the optical system such as a lens 60 or the like. The pan/tilt decision circuit 28 is provided in order to perform camera shake correction without being affected by change in the angular velocity signal due to panning movement or tilting movement. Specifically, in a case of detecting that the angular velocity signal has continuously exhibited a predetermined value during a predetermined period, the pan/tilt decision circuit 28 judges that the image pickup apparatus is in the panning movement state or the tilting movement state. It should be noted that panning movement indicates movement in which the image pickup apparatus is moved in the horizontal direction according to the movement of the subject or the like. Tilting movement indicates movement in which the image pickup apparatus is moved in the vertical direction.

A gain adjustment circuit 30 changes the gain for the angular velocity signal output from the HPF 26 based upon the judgment results from the pan/tilt decision circuit 28. For example, when the image pickup apparatus is not in the panning movement state or the tilting movement state, the gain adjustment circuit 30 performs gain adjustment for the angular velocity signal output from the HPF 26. On the other hand, when the image pickup apparatus is in the panning movement state or the tilting movement state, the gain adjustment circuit 30 performs gain adjustment such that the magnitude of the angular velocity signal output from the HPF 26 is reduced to zero.

An LPF (low-pass filter) serves as an integrating circuit which integrates the angular velocity signal output from the gain adjustment circuit 30 so as to generate an angular signal which indicates the movement amount of the image pickup apparatus. For example, the LPF 32 obtains the angular signal, i.e., the movement amount of the image pickup apparatus, by performing filtering processing using a digital filter.

A centering processing circuit 34 subtracts a predetermined value from the angular signal output from the LPF 32. When the camera shake correction processing is performed in the image pickup apparatus, in some cases, the position of the lens gradually deviates from the base position during continuously executed correction processing, and the position of the lens approaches the limit of the lens movable range. In this case, if the camera shake correction processing is continued, the image pickup apparatus enters the state in which, while the lens can be moved in one direction, the lens cannot be moved in the other direction. The centering processing circuit is provided in order to prevent such a state. The centering processing circuit performs a control operation so as to prevent the lens from approaching the limit of the lens movable range by subtracting a predetermined value from the angular signal.

The angular signal output from the centering processing circuit 34 is adjusted by a gain adjustment circuit 36 so as to be within the signal range of a hall element 70. The angular signal thus adjusted by the gain adjustment circuit 36 is output to a hall equalizer 40.

The hall element 70 is a magnetic sensor that makes use of the Hall effect, which serves as a position detecting means for detecting the position of the lens 60 in the X direction and the Y direction. The analog position signal including the position information with respect to the lens 60 thus obtained by the hall element 70 is amplified by the amplifier circuit 14, following which the analog position signal is transmitted to the ADC 22. The ADC 22 converts the analog position signal thus amplified by the amplifier circuit 14 into a digital position signal. It should be noted that the ADC 22 converts the analog output of the amplifier 12 and the analog output of the amplifier 14 into digital values in a time sharing manner.

The position signal output from the ADC 22 is output to the hall equalizer 40. In the hall equalizer 40, first, the position signal output from the ADC 22 is input to an adder circuit 42. Furthermore, the adder circuit 42 receives, as an input signal, the angular signal adjusted by the gain adjustment circuit 36. The adder circuit 42 adds the position signal and the angular signal thus input. The signal output from the adder circuit 42 is output to a servo circuit 44. The servo circuit 44 generates a signal for controlling the driving operation of a VCM 80 based upon the signal output to the servo circuit 44. In general, the current (VCM driving current) of this signal is 200 to 300 mA. It should be noted that, in the servo circuit 44, filtering processing may be performed using a servo circuit digital filter.

The VCM driving signal output from the servo circuit 44 is converted by a DAC (digital/analog converter) 46 from the digital signal to an analog signal. The analog VCM driving signal is amplified by an amplifier circuit 16, following which the analog VCM driving signal thus amplified is output to the VCM 80. The VCM 80 moves the position of the lens 60 in the X direction and the Y direction according to the VCM driving signal.

Here, description will be made regarding the circuit operation of the image pickup apparatus according to the present embodiment when camera shake does not occur, and the circuit operation thereof when camera shake occurs.

(Operation When Camera Shake Does Not Occur)

When camera shake does not occur, the image pickup apparatus has no angular velocity. Accordingly, the gyro equalizer 24 outputs a signal “0”. The position of the lens 60 driven by the VCM 80 is set such that the optical axis thereof matches the center of the image acquisition device element (not shown) such as a CCD or the like provided to the image pickup apparatus. Accordingly, the analog position signal output from the hall element 70 via the amplifier circuit 14 is converted by the ADC 22 into a digital position signal which indicates “0”. Subsequently, the digital position signal thus converted is input to the hall equalizer 40. When the position signal is “0”, the servo circuit 44 outputs a signal for controlling the VCM 80 so as to maintain the current position of the lens 60.

On the other hand, in a case in which the position of the lens 60 does not match the center of the image acquisition device element, the analog position signal output from the hall element 70 via the amplifier circuit 14 is converted by the ADC 22 into a digital position signal which indicates a value that differs from “0”, following which the digital position signal thus converted is output to the hall equalizer 40. The servo circuit 44 controls the VCM 80 according to the value of the digital position signal output from the ADC 22 such that the value of the position signal is set to “0”.

By repeatedly performing such an operation, the position of the lens 60 is controlled such that the position of the lens 60 matches the center of the image acquisition device element.

(Operation When Camera Shake Occurs)

The position of the lens 60 driven by the VCM 80 is set such that the optical axis thereof matches the center of the image acquisition device element. Accordingly, the analog position signal output from the hall element 70 via the amplifier circuit 14 is converted by the ADC 22 into a digital position signal which indicates “0”, following which the digital position signal thus converted is output to the hall equalizer 40.

On the other hand, when the image pickup apparatus moves due to camera shake, the LPF 32 and the centering processing circuit 34 output an angular signal which indicates the movement amount of the image pickup apparatus based upon the angular velocity signal detected by the gyro sensor 50.

The servo circuit 44 generates a driving signal for the VCM according to a signal obtained by adding the position signal, which is output from the ADC 22 and which indicates “0”, and the angular signal output from the centering circuit. In this case, although the position signal indicates “0”, the angular signal which indicates a value that differs from “0” is added. Accordingly, the servo circuit 44 generates a correction signal which moves the lens 60.

It should be noted that the camera shake correction according to the present embodiment is not so- called electronic camera shake correction whereby the image acquired by the CCD is temporarily stored in memory, and the camera shake components are removed by making a comparison with the subsequent image. The camera shake correction according to the present embodiment is optical camera shake correction such as a lens shift method whereby the lens is optically shifted, or a CCD shift method whereby the CCD is shifted, as described above.

Consequently, optical camera shake correction has the advantage of solving problems that are involved in an arrangement employing an electronic camera shake correction mechanism, i.e., a problem of deterioration of the image quality due to the processing in which a fairly large image is acquired and the image thus acquired is trimmed, a problem of limits in the correction range and the image acquisition magnification due to the CCD size, and a problem in that burring in the static image cannot be corrected in increments of frames. In particular, optical camera shake correction is effectively employed in an arrangement in which a static image is acquired from a high-quality video image.

The VCM 80 moves the lens 60 based upon the correction signal output from the servo circuit 44. Accordingly, such an arrangement allows the image acquisition device element included in the image pickup apparatus to acquire a signal after blurring in the subject image due to camera shake is suppressed. By repeatedly performing such a control operation, such an arrangement provides camera shake correction.

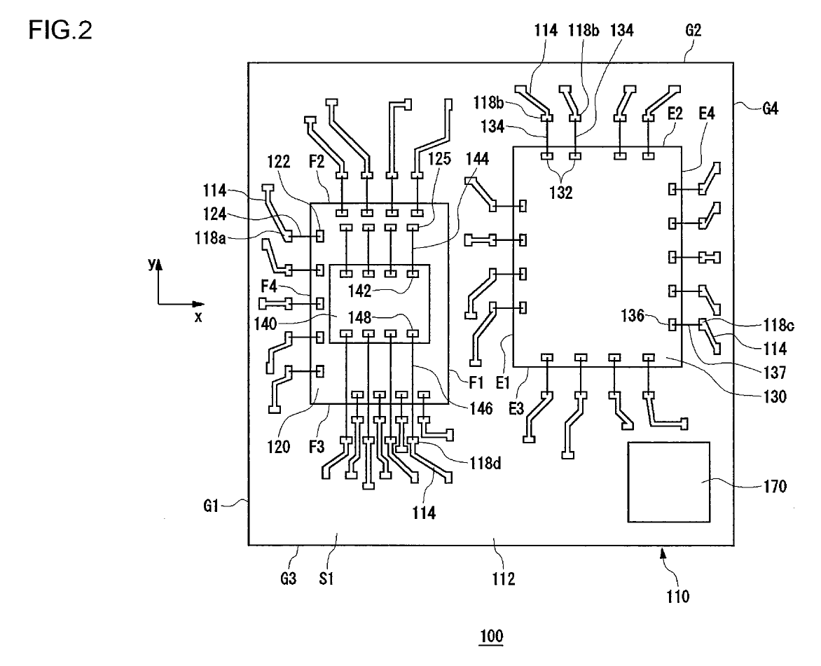

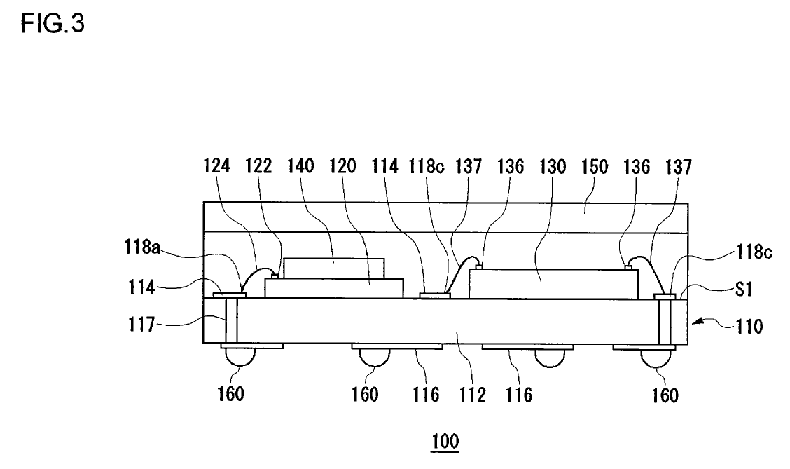

FIG. 2 is a plan view which shows a schematic configuration of a semiconductor module according to an embodiment. FIG. 3 is a cross-sectional view which shows a schematic configuration of the semiconductor module according to the embodiment. It should be noted that, in FIG. 2, a sealing resin 150 described later is not shown.

A semiconductor module 100 includes a wiring substrate 110, a first semiconductor device 120, a second semiconductor device 130, a third semiconductor device 140, a fourth semiconductor device 170, a sealing resin 150, and solder balls 160.

The wiring substrate 110 includes a first wiring layer 114 and a second wiring layer 116 with an insulating resin layer 112 introduced therebetween. The first wiring layer 114 and the second wiring layer 116 are connected to each other through via holes 117 each of which is provided in the insulating resin layer 112 in the form of a through hole. Each solder ball 160 is connected to the second wiring layer 116.

Examples of the materials that may be used to form the insulating resin layer 112 include a melamine derivative such as BT resin etc., liquid crystal polymer, epoxy resin, PPE resin, polyimide resin, fluorine resin, phenol resin, and thermo-setting resin such as polyamide- bismaleimide resin. In order to improve the heat releasing performance of the semiconductor module 100, the insulating resin layer 112 preferably has high heat conductivity. Accordingly, the insulating resin layer 112 preferably contains silver, bismuth, copper, aluminum, magnesium, tin, zinc, alloys thereof, or the like, as a high heat conductivity filler.

Examples of the materials that may be used to form the first wiring layer 114 and the second wiring layer 116 include copper.

The first semiconductor device 120 and the second semiconductor device 130 are mounted alongside on a main surface S1 of the wiring substrate 110. The third semiconductor device 140 is mounted such that it is layered on the first semiconductor device 120. The first semiconductor device 120 is a logic device which corresponds to the camera shake correction unit 20 shown in FIG. 1. The second semiconductor device 130 is a driver device or a power device which corresponds to the signal amplifier unit 10 shown in FIG. 1. The third semiconductor device 140 is a CPU. The third semiconductor device 140 provides a part of the functions of the first semiconductor device 120, or provides the functions of the first semiconductor device 120 instead of the first semiconductor device 120, as necessary. The fourth semiconductor device 170 is a memory device such as EEPROM. The fourth semiconductor device 170 stores data necessary for camera shake correction control operation. The first semiconductor device 120, the second semiconductor device 130, the third semiconductor device 140, and the fourth semiconductor device 170 are sealed with the sealing resin 150 in the form of a package. The sealing resin 150 is formed using the transfer molding method, for example.

The first semiconductor device 120 includes logic signal electrodes 122 each of which allows a logic signal to be input or output. Examples of logic signals to be input to the first semiconductor device 120 include the angular velocity signal and the position signal described above. Typically, the logic signal is provided with a current of 2 mA. Furthermore, examples of the logic signals output from the first semiconductor device 120 include a camera shake correction signal. The logic signal electrode 120 is electrically connected to a substrate electrode 118a provided to the first wiring layer 114 via a bonding wire 124 such as a gold wire or the like.

The second semiconductor device 130 includes current output electrodes 132 each of which allows large current to be output. Examples of large currents output from the second semiconductor device 130 include a current (200 to 300 mA) for driving the VCM. The current output electrode 132 is electrically connected to a substrate electrode 118b provided to the first wiring layer 114 via a bonding wire 134 such as a gold wire or the like. In addition to the current output electrodes 132, the second semiconductor 130 includes chip electrodes 136 each of which is used to input/output a signal to/from other semiconductor devices. The chip electrode 136 is electrically connected to a substrate electrode 118c provided to the first wiring layer 114 via a bonding wire 137 such as a gold wire or the like. It should be noted that the connections via the bonding wires 124, 134, and 137 can be made after the first semiconductor device 120 is mounted on the wiring substrate 110, and the second semiconductor 130 is mounted on the first semiconductor device 120.

As shown in FIG. 2, as viewed from the main surface S1 of the wiring substrate 110, each bonding wire 124 connected to the first semiconductor device 120 is provided across a side of the first semiconductor device 120 other than the side F1 that faces the side E1 of the second semiconductor device 130, i.e., the side F2, F3, or F4. Furthermore, the logic signal electrodes 122 are provided along the sides F2, F3, and F4.

With regard to the second semiconductor device 130, each bonding wire 134 is provided across a side of the second semiconductor device 130 other than the side E1 that faces the side F1 of the first semiconductor device 120. With the present embodiment, each bonding wire 134 is provided across the side E2 adjacent to the side E1. Furthermore, the current output electrodes 132 are provided along the side E2.

Furthermore, the chip electrodes 136 are provided along the sides E1, E3, and E4. Each bonding wire 137 is provided across the side E1, E3, or E4.

It should be noted that the first semiconductor device 120 and the second semiconductor device 130 are mounted at positions with an offset with respect to one another in the y-axis direction shown in FIG. 2. With the present embodiment, the center position of the first semiconductor device 120 is located closer to the center position of the wiring substrate 110 in the y-axis direction. Accordingly, the distance between the side E3 of the second semiconductor device 130 and the side G3 of the wiring substrate 110 is greater than the distance between the side E2 of the second semiconductor device 130 and the side G2 of the wiring substrate 110. On the other hand, the distance between the side F2 of the first semiconductor device 120 and the side G2 of the wiring substrate 110 is the same as that between the side F3 of the first semiconductor device 120 and the side G3 of the wiring substrate 110.

The third semiconductor device 140 includes external electrodes 142 electrically connected to electrode pads 125 provided to the first semiconductor 120 via bonding wires 144. Such an arrangement allows the third semiconductor device 140 to transmit/receive signals to/from the first semiconductor device 120. Furthermore, the third semiconductor device 140 includes external electrodes 148 electrically connected to the substrate electrodes 118b provided to the first wiring layer 114 via bonding wires 146.

The fourth semiconductor device 170 is mounted alongside the side E3 opposite to the side E2 along which the current output electrodes 132 are provided and across which the bonding wires 134 are provided. More preferably, the fourth semiconductor device 170 is provided near the corner of the wiring substrate 110 which is opposite to the current output electrodes 132 and the bonding wires 134 provided to the second semiconductor device 130.

With the semiconductor module 100 described above, with regard to the second semiconductor device 130, the current output electrodes 132 are provided along a side of the second semiconductor device 130 other than the side E1 that faces or is adjacent to the side F1 of the first semiconductor device 120. Furthermore, each bonding wire 134 is provided across a side of the second semiconductor device 130 other than the side E1. With such an arrangement, the current output electrodes 132 and the bonding wires 134 are provided at positions distanced from the first semiconductor device 120. This prevents noise from occurring in the first semiconductor device 120 due to the effect of large current output from the second semiconductor device 130.

Furthermore, with regard to the first semiconductor device 120, the logic signal electrodes 122 and the bonding wires 124 are not provided along/across the side F1 that faces or is adjacent to the side E1 of the second semiconductor device 130 which outputs large current. Such an arrangement prevents noise from occurring in the first semiconductor device 120 due to the effect of large current output from the second semiconductor device 130.

In addition, the fourth semiconductor device 170 is provided at a distant position from the current output electrodes 132 and the bonding wires 134. Thus, such an arrangement prevents noise from occurring in the fourth semiconductor device 170. As a result, such an arrangement improves the operation reliability of the fourth semiconductor device 170, thereby improving the operation reliability of the semiconductor module 100.

Moreover, the distance between the side E3 of the second semiconductor device 130 and the side G3 of the wiring substrate 110 is greater than the distance between the side E2 of the second semiconductor device 130 and the side G2 of the wiring substrate 110. Thus, such an arrangement ensures the region for mounting the fourth semiconductor device 170.

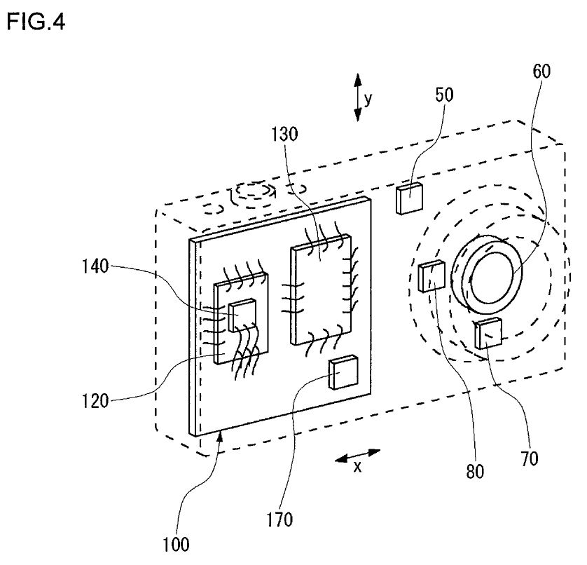

FIG. 4 is a transparent perspective view which shows a digital camera including the semiconductor module according to the above-described embodiment. A digital camera includes the gyro sensor 50, the lens 60, the hall element 70, the VCM 80, and the semiconductor module 100. As shown in FIG. 2 and FIG. 3, the semiconductor module 100 includes the first semiconductor device 120, the second semiconductor device 130, and the fourth semiconductor device 170 mounted alongside one another. Furthermore, the third semiconductor device 140 is mounted such that it is layered on the first semiconductor device 120. It should be noted that FIG. 4 shows a configuration of the semiconductor module 100 in a simplified manner with the components other than the first semiconductor device 120, the second semiconductor device 130, the third semiconductor device 140, and the fourth semiconductor device 170 simplified and omitted as appropriate.

Even in a case in which the first semiconductor device 120 and the second semiconductor device 130 are mounted close to one another, such an arrangement provides a digital camera with a further reduced size without involving reduction in the operation reliability.

The present invention is not restricted to the above-described embodiments. Also, various modifications may be made with respect to the layout and so forth based upon the knowledge of those skilled in this art. Such modifications of the embodiments are also encompassed by the scope of the present invention.

The image pickup apparatus described in the present specification is not restricted to the above-described digital camera. Also, the image pickup apparatus described in the present specification may be a video camera, a camera mounted on a cellular phone, a security camera, etc. The present invention can be effectively applied to such arrangements in the same way as with the digital camera.

What is claimed is:

1. A semiconductor module comprising:
a wiring substrate including substrate electrodes on one main surface thereof;
a first semiconductor device which is mounted on the wiring substrate, and which includes a logic signal electrode via which a logic signal is input or output;
a second semiconductor device which is mounted alongside the first semiconductor device, and which includes a current output electrode via which large current is output;
a first bonding wire which electrically connects the logic signal electrode and the corresponding substrate electrode; and
a second bonding wire which electrically connects the current output electrode and the corresponding substrate electrode,
wherein, as viewed from the main surface side of the wiring substrate, the first bonding wire is provided across a side of the first semiconductor device that does not face a side of the second semiconductor device.

2. A semiconductor module according to claim 1, wherein the logic signal electrode is provided along a side of the first semiconductor device which does not face a side of the second semiconductor device.

3. A semiconductor module according to claim 1, wherein the first semiconductor device outputs an anti-shake signal used to correct blurring due to shaking applied to an image pickup apparatus,
and wherein the second semiconductor device outputs large current to be supplied to a driving means which drives a lens of the image pickup apparatus according to the anti-shake signal.

4. A semiconductor module according to claim 2, wherein the first semiconductor device outputs a anti-shake signal used to correct blurring due to shaking applied to an image pickup apparatus,
and wherein the second semiconductor device outputs large current to be supplied to a driving means which drives a lens of the image pickup apparatus according to the anti-shake signal.

5. A semiconductor module according to claim 3, wherein the driving means is a voice coil motor.

6. A semiconductor module according to claim 4, wherein the driving means is a voice coil motor.

7. A semiconductor module according to claim 1, wherein the logic signal electrode is provided along a side of the first semiconductor device which side differs from a side facing a side of the second semiconductor device.

8. A semiconductor module according to claim 2, wherein the logic signal electrode is provided along a side of the first semiconductor device which side differs from a side facing a side of the second semiconductor device.

9. A semiconductor module according to claim 3, wherein the logic signal electrode is provided along a side of the first semiconductor device which side differs from a side facing a side of the second semiconductor device.

10. A semiconductor module according to claim 1, wherein the distance between the side of the second semiconductor device across which the second bonding wire is provided and the side of the wiring substrate facing the aforementioned side is smaller than the distance between the opposite side of the second semiconductor device opposite to the side across which the second bonding wire is provided and the side of the wiring substrate facing the opposite side.

11. A semiconductor module according to claim 2, wherein the distance between the side of the second semiconductor device across which the second bonding wire is provided and the side of the wiring substrate facing the aforementioned side is smaller than the distance between the opposite side of the second semiconductor device opposite to the side across which the second bonding wire is provided and the side of the wiring substrate facing the opposite side.

12. A semiconductor module according to claim 3, wherein the distance between the side of the second semiconductor device across which the second bonding wire is provided and the side of the wiring substrate facing the aforementioned side is smaller than the distance between the opposite side of the second semiconductor device opposite to the side across which the second bonding wire is provided and the side of the wiring substrate facing the opposite side.

13. A semiconductor module according to claim 10, wherein the first semiconductor device and the second semiconductor device are arranged with an offset with respect to one another in the direction orthogonal to the side of the second semiconductor device across which the second bonding wire is provided.

14. A semiconductor module according to claim 11, wherein the first semiconductor device and the second semiconductor device are arranged with an offset with respect to one another in the direction orthogonal to the side of the second semiconductor device across which the second bonding wire is provided.

15. A semiconductor module according to claim 12, wherein the first semiconductor device and the second semiconductor device are arranged with an offset with respect to one another in the direction orthogonal to the side of the second semiconductor device across which the second bonding wire is provided.

16. An image pickup apparatus including a semiconductor module according to claim 1.

17. An image pickup apparatus including a semiconductor module according to claim 2.

18. An image pickup apparatus including a semiconductor module according to claim 3.
